(19) United States
(12) Patent Application Publication
(10) Pub. No.: US 2026/0353812 A1
(43) Pub. Date: Nov. 5, 2026

(54) TRENCH ISOLATION STRUCTURE FOR A SEMICONDUCTOR DEVICE

(71) Applicant: TEXAS INSTRUMENTS INCORPORATED, DALLAS, TX (US)

(72) Inventor: Enis TUNCER, DALLAS, TX (US)

(21) Appl. No.: 19/194,966

(22) Filed: Apr. 30, 2025

(51) Int. Cl. H10D 89/10; H10W 10/00; H10W 10/17; H10W 44/00; H10W 70/40; H10W 72/50; H10W 90/00

(52) U.S. Cl. CPC H10D 89/10; H10W 10/014; H10W 10/17; H10W 44/601; H10W 70/417; H10W 72/536; H10W 90/756

(57) ABSTRACT

In one example, a semiconductor device is provided. The semiconductor device comprises a semiconductor wafer having a front side opposite a back side in a first direction. The semiconductor device includes an active circuitry layer formed on the front side of the semiconductor wafer. The active circuitry layer includes a bond pad structure on a first active surface opposite a second active surface in the first direction. The second active surface is affixed to the front side of the semiconductor wafer. The semiconductor device includes a first filled trench that is a first closed shape that bounds the bond pad structure and extends through the semiconductor wafer from the front side to the back side. The semiconductor device includes a second filled trench arranged is a second closed shape that bounds the first filled trench and extends through the semiconductor wafer from the front side to the back side.

### TECHNICAL FIELD

This description relates the use multiple filled trenches to improve the voltage capability of semiconductor devices.

### BACKGROUND

Integrated circuits are produced by means of a fabrication process which converts a circuit design into an operable device. The fabrication process transforms a substrate of semiconductor material, such as silicon, into a device with multiple layers, each having a specific pattern of structures and interconnections. A finished integrated circuit is usually comprised of a multitude of smaller devices which are electrically connected in a desired manner. In order for an integrated circuit to properly operate, the component devices are electrically isolated from each other. A variety of isolation techniques may be required because different types of integrated circuits have differing electrical and structural characteristics, and this can affect the type of structure required for effective isolation. The isolation techniques may vary in such attributes as minimum isolation spacing, planarity of the final surface, complexity of the isolation process, and the density of defects created during the process.

### SUMMARY

In one example, a semiconductor device is provided. The semiconductor device comprises a semiconductor wafer having a front side that is opposite a back side in a first direction. The semiconductor device also including an active circuitry layer formed on the front side of the semiconductor wafer. The active circuitry layer includes a bond pad structure on a first active surface that is opposite a second active surface in the first direction. The second active surface is affixed to the front side of the semiconductor wafer. The semiconductor device further includes a first filled trench that is a first closed shape that bounds the bond pad structure and extends through the semiconductor wafer from the front side to the back side. The semiconductor device yet further includes a second filled trench arranged is a second closed shape that bounds the first filled trench and extends through the semiconductor wafer from the front side to the back side.

Another example is a method for forming a semiconductor device. The method includes providing a semiconductor wafer having a front side that is opposite a back side in a first direction. The method also includes forming an active circuitry layer on the front side of the semiconductor wafer. The active circuitry layer includes a bond pad structure on a first active surface that is opposite a second active surface in the first direction. The second active surface is in contact with the front side of the semiconductor wafer. The method further includes etching a first trench that is a first closed shape that bounds the bond pad structure and extends through the semiconductor wafer from the front side to the back side. The method yet further includes etching a second trench that is a second closed shape that bounds the first trench and extends through the semiconductor wafer from the front side to the back side. The method includes forming a first filled trench in the first trench and a second filled trench in the second trench with a dielectric material.

In yet another example, an example integrated circuit (IC) device is provided. The IC device includes a semiconductor wafer having a front side that is opposite a back side in a first direction. The IC device also includes an active circuitry layer formed on the front side of the semiconductor wafer. The active circuitry layer includes a first bond pad structure and a second bond pad structure on a first active surface that is opposite a second active surface in the first direction. The second active surface is in contact with the front side of the semiconductor wafer. The IC device further includes a first filled trench being a first closed shape that bounds the first bond pad structure and extends through the semiconductor wafer from the front side to the back side. The IC device yet further includes a second filled trench being a second closed shape that bounds the first filled trench and extends through the semiconductor wafer from the front side to the back side. The first filled trench and the second filled trench separate the first bond pad structure and the second bond pad structure forming a high voltage region between the first filled trench and the first bond pad structure and a low voltage region at the second bond pad structure.

### BRIEF DESCRIPTION OF THE DRAWINGS

FIG. 1 illustrates a perspective view of an example semiconductor device having a trench isolation structure.

FIG. 2 illustrates a cross-sectional view of the example semiconductor device having a trench isolation structure.

FIG. 3 illustrates a perspective view of an example integrated circuit (IC) device having a trench isolation structure.

FIGS. 4-14 illustrate example stages of an example method for forming a semiconductor device having a trench isolation structure.

FIG. 15 illustrates a flowchart of an example method for forming a semiconductor device having a trench isolation structure.

### DETAILED DESCRIPTION

The structures and methods of the present disclosure can be used to provide electrical isolation between regions of a semiconductor device that operate at different voltages. The different voltage regions may result from different components integrated with or connected to the single semiconductor device. However, linking devices that operate at different voltages, such as a high voltage device and a low voltage device, can have deleterious effects on the operation of the semiconductor device and/or the low voltage device. Thus, systems and methods herein employ structures to isolate the high voltage devices from the low voltage devices and protect the semiconductor device and/or the low voltage device. In particular, a trench isolation structure is used to isolate the high voltage device and/or the low voltage device.

The trench isolation structure includes at least two filled-trenches, in which a first filled-trench is bounded by a second filled-trench. The plurality of filled trenches are formed through the back side of the wafer, and do not extend through the front side of the wafer to reduce impact on active circuitry. Reducing the impact on the active circuitry of the semiconductor devices further reduces damage during fabrication and avoids weakening the structural integrity of the semiconductor device. Furthermore, because the plurality of filled trenches are formed through the back side of the wafer, the trench structure described herein obviates the need for an insulation layer between the wafer and the active layer.

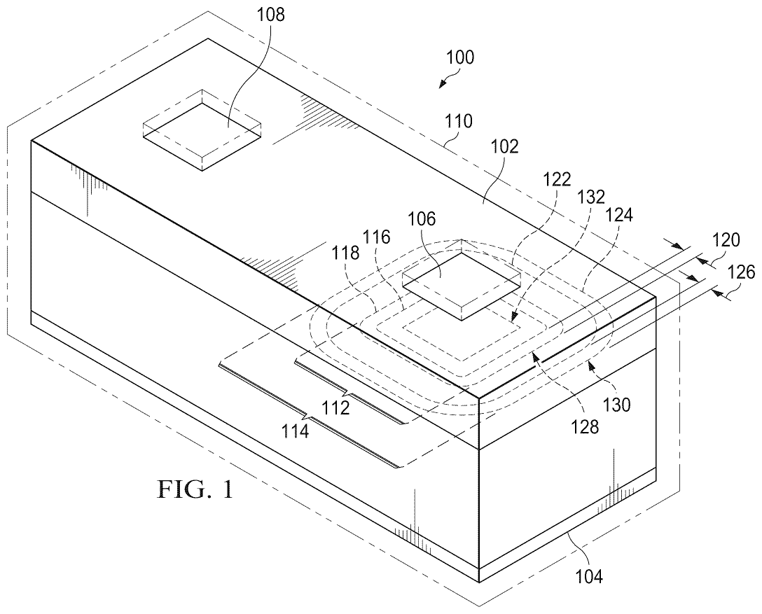

FIG. 1 illustrates a perspective view of a semiconductor device 100 having a trench isolation structure. The semiconductor device 100 has an upper surface 102 opposite a lower surface 104 in a first direction. The semiconductor device 100 includes a first bond pad structure 106 and a second bond pad structure 108 in the upper surface 102 of the semiconductor device 100. The bond pad structures 106, 108 are small areas or pads on the surface of the semiconductor device 100 that are designed for the attachment of external electrical connections, sometimes in the form of bond wires. These external connections are used to link the semiconductor device 100 to other components, such as other IC packages, PCBs (printed circuit boards) or other parts of an electronic system. The semiconductor device 100 may have a protective covering 110, such as being encapsulated in a mold compound, to protect active circuitry electrically connected to the first bond pad structure 106 and the second bond pad structure 108. The first bond pad structure 106 and the second bond pad structure 108 are accessible through respective openings in the protective covering 110.

The semiconductor device 100 includes a plurality of filled trenches. In some examples, the filled trenches isolate the bond pad structures 106, 108 as well as isolate regions corresponding to the respective bond pad structures 106, 108. The filled trenches include, at least, a first filled trench 112 and a second filled trench 114. The first filled trench 112 and the second filled trench 114 are formed in closed shapes (e.g., circumscribing the bond pad structure 106). The closed shape of the filled trenches 112, 114 are, for example, a triangle, a quadrilateral, pentagon, hexagon, etc. As one example, a first shape of the first filled trench 112 is a quadrilateral having four edges and four rounded corners. Likewise, a second shape of the second filled trench 114 is also a quadrilateral having four edges and four rounded corners. The first shape and the second shape may be the same or different depending on the application of the semiconductor device 100.

The filled trenches 112, 114 are disposed in a wafer underlying the upper surface 102 by the active circuitry. The filled trenches 112, 114 are filled with dielectric material. The dielectric material is nonconductive, and is, for example, parylene, polybenzoxazole (PBO), SU-8, spin-on-glass (SOG), polyimide (PI), polyphenylene ether (PPE), polyphenylene oxide (PPO), Bismaleimide (BMI), Benzocyclobutene (BCB), liquid crystal polymer, epoxy, polyphenylene ether, polyetherimide, polysulfone, silicon nitride, and silicon dioxide or other suitable material with similar properties. In some examples, the first filled trench 112 is bounded (e.g., circumscribed) by the second filled trench 114 and separated by the wafer material. The first filled trench 112 and the second filled trench 114 may be concentric and centered about the first bond pad structure 106. The first filled trench 112 and the second filled trench 114 have capacitance values. The capacitance values are directly proportional to the area of the capacitor. The first filled-trench 112 has a first capacitance value, C₁, and the second filled-trench 114 has a second capacitance value, C₂.

As an example, the first filled trench 112 has a first inner periphery 116 defined by a sidewall of the first filled trench 112 proximate to the first bond pad structure 106. A first outer periphery 118 is defined by a sidewall of the first filled trench 112 distal to the first bond pad structure 106. A first trench thickness 120 is the distance between the first inner periphery 116 and the first outer perimeter 118 in the second direction. A first trench height is the length of the first filled trench 112 in the first direction. Each periphery 116 and 118 has a length that defines a respective perimeter thereof. Accordingly, the area, A₁, of the first filled trench 112 is given by:

$${A}_{1} = ( first trench height ) * \frac{( ( first outer perimeter ) + ( first inner perimeter ) )}{2}$$

The first capacitance value, C₁, of the first filled trench 112, at a midpoint between the first inner perimeter 116 and the first outer perimeter 118 is given by:

$${C}_{1} = {ε}_{d} {ε}_{0} \frac{{A}_{1}}{trench thickness}$$

where ε_{d} is the dielectric constant of the dielectric material and ε₀ is the permittivity of a vacuum. The manner in which capacitance is calculated is based on the shape of the filled trenches. Generally, capacitance is given by the charge stored on the trench (in Coulombs) over the voltage across the trench (in Volts). The charge stored is based on the shape of the filled trench. Accordingly, changes in the shape of the filled trench, affect the capacitance of the filled trench.

The second capacitance value of the second filled trench 114 is determined similarly. In particular, the second filled trench 114 has a second inner periphery 122 defined by a sidewall of the second filled trench 114 proximate to the first bond pad structure 106. A second outer periphery 124 is defined by a sidewall of the second filled trench 114 distal to the first bond pad structure 106. A second trench thickness 126 is the distance between the second inner periphery 122 and the second outer periphery 124 in the second direction. A second trench height is the length of the second filled trench 114 in the first direction. Accordingly, the area, A₂, of the second filled trench 114 is given by:

$$A = ( second trench height ) * \frac{( ( second outer perimeter ) + ( second inner perimeter ) )}{2}$$

The second capacitance value, C₂, of the second filled trench 114, at a midpoint between the second inner perimeter 122 and the second outer perimeter 124 is given by:

$${C}_{2} = {ε}_{d} {ε}_{0} \frac{{A}_{2}}{trench thickness}$$

The bounded area of the first inner perimeter 116 of the first filled trench 112 defines a first voltage region 128 having a first voltage value, V₁. The first voltage, V₁, is based on the component electrically connected to the first bond pad structure 106. For example, the first bond pad structure 106 is electrically connected to a high voltage device and the first voltage, V₁, is correspondingly high. The region outside of the second outer perimeter 124 of the second filled trench 114 defines a second voltage region 130 having a second voltage value, V₂. Continuing the example from above, the second bond pad structure 108 is electrically connected to a low voltage device and the second voltage, V₂, is correspondingly low.

The trench isolation structure, including the first filled trench 112 and the second filled trench 114, isolates the first voltage region 128 from the second voltage region 130 with a floating voltage region 132. The floating voltage region 132 is the area between the first outer perimeter 118 of the first filled trench 112 and the second inner perimeter 122 of the second filled trench 114. The floating voltage region 132 has a floating voltage value, Vₓ, is determined by:

$${V}_{x} = ( {V}_{1} - {V}_{2} ) \frac{{C}_{1}}{{C}_{1} + {C}_{2}}$$

The floating voltage region 132 generated by the trench isolation structure provides electrical isolation between the first bond pad structure 106 and the second bond pad structure 108. Because the floating voltage is based on the dimensions of the filled trenches 112, 114, the closed shape of the filled trenches 112, 114 can be configured to achieve a predetermined floating voltage based on an application of the semiconductor device 100. While the trench isolation structure is described with respect to the first filled trench 112 and the second filled trench 114, more trenches may be formed in the semiconductor device. For example, the second filled trench 114 may be bounded by a third filled trench.

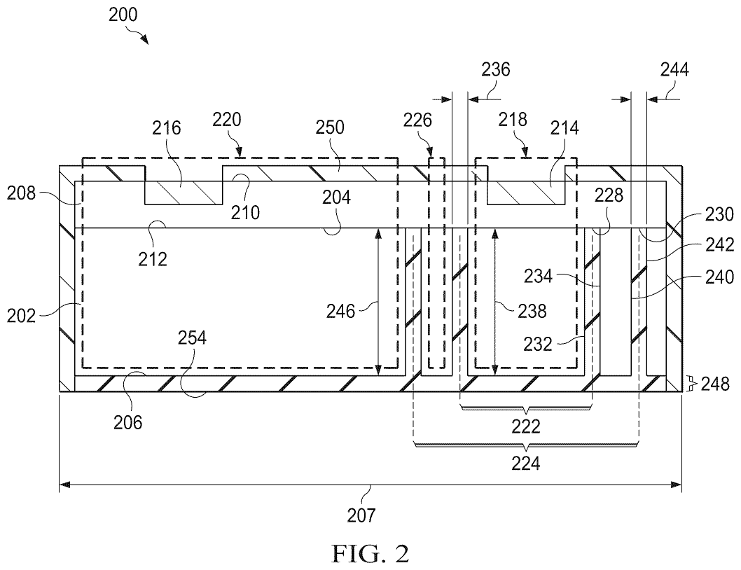

FIG. 2 illustrates a cross-sectional view of the semiconductor device 200 having a trench isolation structure. The semiconductor device 200 (e.g., the semiconductor device 100 of FIG. 1) includes a wafer 202 having a front side 204 opposite a back side 206 in a first direction. The wafer 202 is a substrate, such as silicon, silicon carbide, or other suitable material, either in substantially pure form or in combination with additional materials. As another example, the wafer 202 is a single crystal material, such as a single crystal silicon substrate. As yet another example, the wafer 202 is a complementary metal-oxide semiconductor (CMOS) substrate. The formation of the wafer 202 is dependent on the application of the resulting IC device. The wafer may additionally include electrical components. The wafer 202 has a semiconductor thickness 207 in a second direction, approximately orthogonal to the first direction.

Active circuitry 208 is formed on the front side 204 of the wafer 202. The active circuitry 208 extends from a first active surface 210 to a second active surface 212. The second active surface 212 of the active circuitry is in contact with and/or extends into the front side 204 of the semiconductor wafer 202. The active circuitry includes a first bond pad structure 214 (e.g., the first bond pad structure 106 of FIG. 1) and a second bond pad structure 216 (e.g., the second bond pad structure 108 of FIG. 1) at the first active surface 210 of the active circuitry 208. The active circuitry 208 may additionally include components such as one or more passive elements (e.g., resistors, capacitors, transistors, inductors, etc.) and/or one or more sources (e.g., voltage and/or current sources, etc.). In some examples, the active circuitry 208 is electrically connected to high voltage devices such as a high voltage electrostatic discharge (ESD) device with a high voltage field MOSFET, etc. through the first bond pad structure 214 and/or the second bond pad structure 216.

The different components of the active circuitry 208 result in different voltage regions including a first voltage region 218 and a second voltage region 220 during operation. The first voltage region 218 corresponds a first voltage value and the second voltage region 220 corresponds to a second voltage value different than the first voltage. The first voltage value may be generated during operation by a high voltage device electrically connected to the first bond pad structure 214. The second voltage value may be generated during operation by a low voltage device electrically connected to the second bond pad structure 216.

A floating voltage region 226 is positioned between the first voltage region 218 and the second voltage region 220. The floating voltage region 226 has a floating voltage value that is generated during operation based on the capacitance values of a first filled trench 222 (e.g., the first filled trench 112 of FIG. 1) and a second filled trench 224 (e.g., the second filled trench 114 of FIG. 1). Additionally, the floating voltage value is based on the applied current and/or voltage of the semiconductor device 200 during operation. The filled trenches 222, 224 are closed shapes filled with dielectric material, such as described herein. As one example, the closed shape is a quadrilateral. Because FIG. 2 is shown is a cutaway cross-sectional view, the proximate trenches on either side of the first bond pad structure 214 form the first filled trench 222, and the distal trenches on either side of the first bond pad structure 214 form the second filled trench that bounds the first filled trench 222.

The filled trenches 222, 224 extend from the back side 206 of the wafer 202 through the wafer/substrate 202 and toward the active circuitry but do not extend into the active circuitry 208. For example, the first filled trench 222 extends from the back side 206 of the wafer 202 to a first trench terminus 228 at the front side 204 of the wafer 202. The first filled trench 222 does not extend past the second active surface 212 of the active circuitry 208. The second filled trench 224 extends from the back side 206 of the wafer 202 to a second trench terminus 230 at the front side 204 of the wafer 202. The second filled trench 224 does not extend past the second active surface 212 of the active circuitry 208.

The first filled trench 222 has a first inner perimeter (e.g., the first inner perimeter 116 of FIG. 1) defined by a first inner sidewall 232 of the first filled trench 222 proximate to the first bond pad structure 214. A first outer perimeter (e.g., the first outer perimeter 118 of FIG. 1) is defined by a first outer sidewall 234 of the first filled trench 222 distal to the first bond pad structure 214. Accordingly, the first inner sidewall 232 is formed between the first bond pad structure 214 and the first outer sidewall 234.

A first trench thickness 236 (e.g., the first trench thickness 120 of FIG. 1) is the distance between the first inner sidewall 232 and the first outer sidewall 234 in the second direction. The semiconductor thickness 207 is at least approximately ten times the first trench thickness 236. A first trench height 238 is the length of the first filled trench 222 in the first direction. For example, the first trench height 238 is the distance from the front side 204 of the wafer 202 to the back side 206 in the first direction. The first capacitance value, C₁, of the first filled trench 222 is determined, in the manner described above, based on the dimensions of the first filled trench 222, including the first trench thickness 236, its perimeter length, and the first trench height 238.

The second filled trench 224 has a second inner perimeter (e.g., the second inner perimeter 122 of FIG. 1) defined by a second inner sidewall 240 of the second filled trench 224 proximate to the first bond pad structure 214. A second outer perimeter (e.g., the second outer perimeter 124 of FIG. 1) is defined by a second outer sidewall 242 of the second filled trench 224 distal to the first bond pad structure 214. A second trench thickness 244 (e.g., the second trench thickness 126 of FIG. 1) is the distance between the second inner sidewall 240 and the second outer sidewall 242 in the second direction. The semiconductor thickness 207 is at least approximately ten times the second trench thickness 244. A second trench height 246 is the length of the second filled trench 224 in the first direction. For example, the second trench height 246 is the distance from the front side 204 of the wafer 202 to the back side 206 in the first direction. The second capacitance value, C₂, of the second filled trench 224 is determined, in the manner described above, based on the dimensions of the second filled trench 224, including the second trench thickness 244, its perimeter length, and the second trench height 246.

In some examples, an insulation layer 248 is formed of the dielectric material. The insulation layer 248 extends from the back side 206 of the wafer 202 to an insulation surface 254. The insulation layer 248 provides additional isolation and protection. A mold compound 250 is applied to at least a portion of the semiconductor device 200. The mold compound 250 (e.g., a polymer or resin material) may protect the components of a packaged semiconductor device from the outside environment (e.g., specifically from dust, liquid, light, contaminants in the outside environment), and may prevent undesired contact with conductive surfaces or members on the packaged semiconductor device during operations. At least one surface of the first bond pad structure 214 and a second bond pad structure 216 are free of the mold compound 250 to be electrically accessible.

FIG. 3 illustrates a perspective view of an example integrated circuit (IC) device having a plurality of trench isolation structures. The packaged IC device 300 includes a wafer 302 (e.g., the wafer 202 of FIG. 2) having active circuitry 304 (e.g. the active circuitry 208 of FIG. 2) formed on a front side 306 of the wafer 302. A multi-layer conductive contact including a plurality of bond pad structures 308 (e.g., the first bond pad structure 106 and the second bond pad structure 108 of FIG. 1, and the first bond pad structure 214 and the second bond pad structure 216 of FIG. 2) is formed atop of and coupled to the active circuitry 304. The bond pad structures 308 may include a plurality of layers of different metal materials that are positioned within (e.g., embedded in) a mold compound 310 (e.g., the protective covering 110 of FIG. 1, the mold compound 250 of FIG. 2). The mold compound 310 protects the IC device 300 and mitigates electrical shorts between the bond pad structures 308 during operations. The mold compound 310 covers at least a portion of the front side 306 of the wafer 302.

In some examples, the bond pad structures 308 are coupled to conductive leads 312 (e.g., pins) by bond wires 314. In other examples, the IC device 300 may include a quad flat no-lead (QFN) package or another package type and the conductive leads 312 may be arranged and designed for use therein according to the package type. The bond pad structures 308 of the IC package are coupled to the respective conductive leads 312 by respective bond wires 314.

One or more of the bond pad structures 308 are isolated by a trench isolation structure 316 that includes a plurality of filled trenches (e.g., the first filled trench 112 and the second filled trench 114 of FIG. 1, the first filled trench 222 and the second filled trench 224 of FIG. 2). The filled trenches are closed shapes that surround a respective bond pad structure 308. Accordingly, the IC device 300 is shielded from high voltage devices electrically connected to the conductive leads 312. As one example, the IC device 300 is configured for a maximum repetitive peak isolation application that isolates high voltage devices.

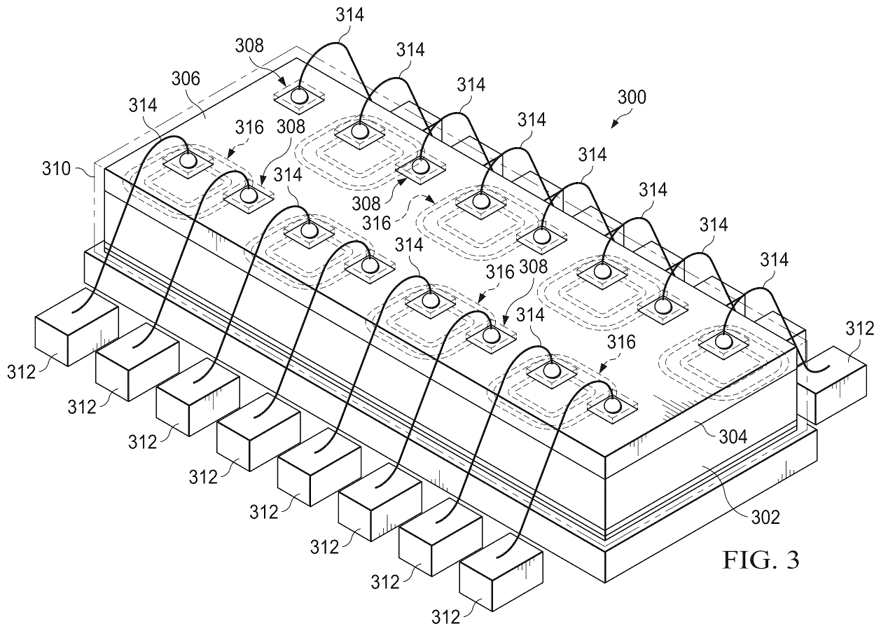

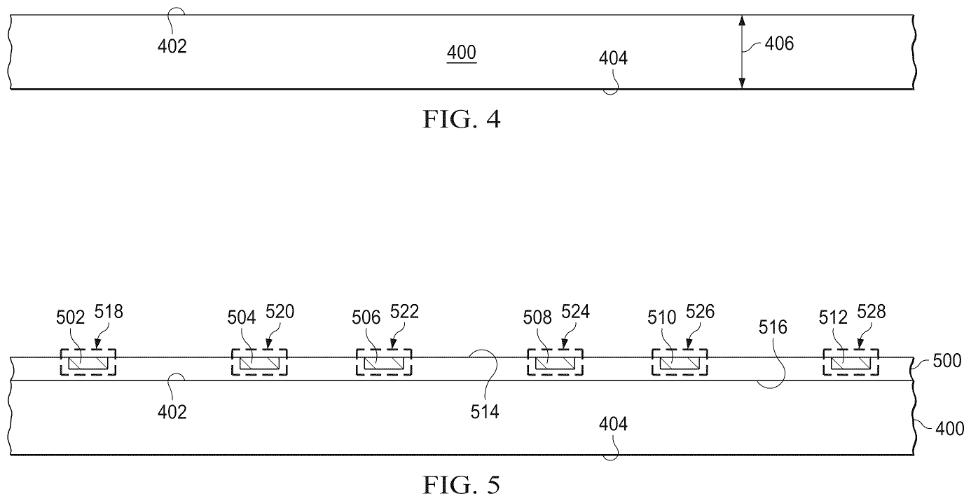

FIG. 4 illustrates an example of a first stage of a method for forming an IC device. In the first stage, a wafer 400 (e.g., the wafer 202 of FIG. 2, the wafer 302 of FIG. 3) is provided. The wafer 400 has a front side 402 (e.g., the front side 204 of FIG. 2, the front side 306 of FIG. 3) opposite a back side 404 (e.g., the back side 206) in a first direction. The wafer 400 is formed of a substrate material, such as silicon, germanium, gallium arsenide, indium phosphide, silicon carbide, or other material suitable for structural support. The wafer 400 has a wafer thickness 406 defined between the front side 402 and the back side 404.

FIG. 5 illustrates an example of a second stage of the method for forming the IC device. Active circuitry 500 (e.g., the active circuitry 208 of FIG. 2, the active circuitry 304 of FIG. 3) is formed on the front side 402 of the wafer 400. The active circuitry 500 includes or is electrically connected to one or more high voltage devices. As one example, the high voltage devices include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, etc. The active circuitry 500 may also include or electrically connected to passive circuit elements, such as capacitors, inductors, fuses, resistors, and interconnects. In some examples, the active circuitry 500 is formed of a printed circuit board (PCB).

The different devices, whether the devices are high voltage devices, passive devices, etc., have different voltages causing voltage differentials to exist on the active circuitry 500. In some examples, the high voltage devices and the passive circuit elements are electrically connected to bond pad structures (e.g., the first bond pad structure 106 and the second bond pad structure 108 of FIG. 1, and the first bond pad structure 214 and the second bond pad structure 216 of FIG. 2, the bond pad structures 308 of FIG. 3). The bond pad structures include a first bond pad structure 502, a second bond pad structure 504, a third bond pad structure 506, a fourth bond pad structure 508, a fifth bond pad structure 510, and sixth bond pad structure 512. The bond pad structures 502-512 are formed in a first active surface 514 (e.g., the first active surface 210 of FIG. 2) that is opposite a second active surface 516 (e.g., the second active surface 212 of FIG. 2) of the active circuitry 500.

Voltage regions (e.g., the voltage regions 126-130 of FIG. 1, the voltage regions 218-222 of FIG. 2) are formed during operation in the active circuitry 500 due to the different devices of the active circuitry 500. For example, a first voltage region 518, a second voltage region 520, a third voltage region 522, a fourth voltage region 524, a fifth voltage region 528, and a sixth voltage region 528 are formed based on different voltages generated by different components of the active circuitry 500. For example, the voltage regions 518-528 may be formed about the bond pad structures 502-512. In some examples, the voltage regions 518-528 are bounded by the first active surface 514 to the second active surface 516. In other examples, the voltage regions 518-528 extend beyond the second active surface 516 into the wafer 400. As one example, the distance that the voltage regions 518-528 extend into the wafer 400 through the front side 402 is proportional to the value of the voltage in the voltage region.

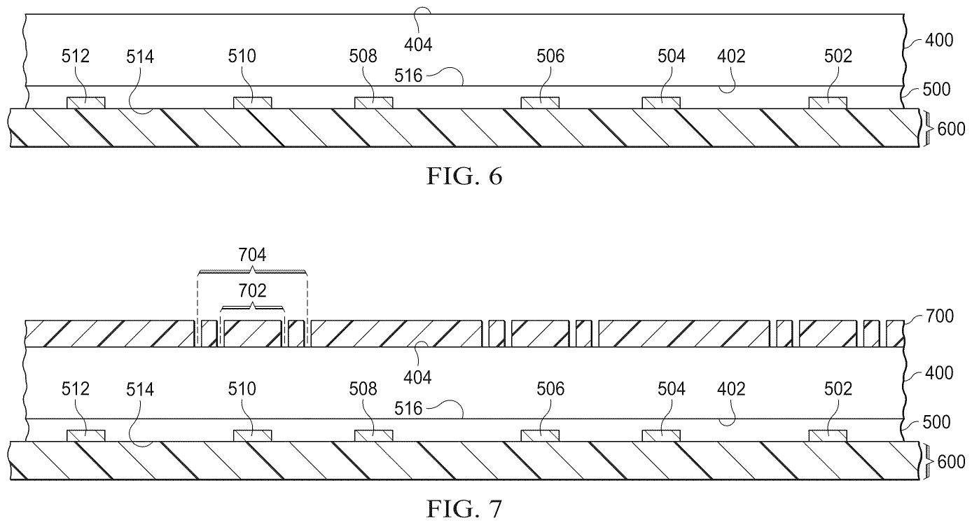

In some examples, the initial wafer thickness of the wafer 400, defined by the distance between the front side 402 and the back side 404, is adjusted by back grinding. In a third stage, as shown in the example of FIG. 6, a back grinding tape 600 is applied to the first active surface 514 of the active circuitry 500. The back grinding tape 600 supports the wafer 400 during back grinding. For example, in the third stage, the back side 404 of the wafer 400 is ground with a grinding tool (not shown) to remove material from the back side 404. Accordingly, the wafer 400 is positioned upside down for back grinding. Additionally, the back grinding tape 600 can act as a layer for protecting the first active surface 526 of the active circuitry 500 during back grinding.

FIG. 7 illustrates an example of a fourth stage of the method for forming the IC device. In the fourth stage, a photomask 700 is applied to the back side 404 of the wafer 400. In one example, the photomask 700 is opaque, blocking a portion of the back side 404 from irradiation used for patterning. The photomask 700 includes openings that allow radiation to impact the back side 404. The openings include a first shape 702 and a second shape 704, shown here in a cross-sectional view. The first shape 702 and the second shape 704 are closed shapes, for example, a triangle, a quadrilateral, pentagon, hexagon, etc. For example, the first closed shape 702 and the second closed shape 704 are quadrilaterals having four edges and four rounded corners. In some examples, the first shape 702 bounds the second shape 704.

FIG. 8 illustrates an example of a fifth stage of the method for forming the IC device. The irradiated portions of the wafer are removed by applying a developer material to form trenches in the wafer 400. For example, a dry plasma etch is performed to remove the irradiated portions from the back side 404. The substrate material of the wafer 400 is etched from the back side 404 to the front side 402 of the wafer 400 and the photomask 700 is removed. The etched substrate material forms a first trench 802 in the first shape 702 and a second trench 804 in the second shape 704.

The first trench 802 has a first inner sidewall 806 (e.g., the first inner sidewall 232 of FIG. 2) that is opposite a first outer sidewall 808 (e.g., the first outer sidewall 234 of FIG. 2) in a second direction approximately orthogonal to the first direction. The first inner sidewall 806 is formed between the first bond pad structure 502 and the first outer sidewall 808. A first trench thickness 810 (e.g., the first trench thickness 120 of FIG. 1, the first trench thickness 236 of FIG. 2) is defined as a distance between the first inner sidewall 806 and the first outer sidewall 808. The first trench 802 extends from the back side 404 of the wafer 400 to a first trench terminus 812 (e.g., the first trench terminus 228 of FIG. 2) at the second active surface 516 of the active circuitry 500. By halting the etching before extending into the active circuitry 500, the functioning of the active circuitry is not impacted.

The second trench 804 has a second inner sidewall 814 (e.g., the second inner sidewall 240 of FIG. 2) that is opposite a second outer sidewall 816 (e.g., the second outer sidewall 242 of FIG. 2) in a second direction approximately orthogonal to the first direction. The second inner sidewall 814 is formed between the bond pad structure and the second outer sidewall 816. A second trench thickness 818 (e.g., the second trench thickness 126 of FIG. 1, the second trench thickness 244 of FIG. 2) is defined as a distance between the second inner sidewall 814 and the second outer sidewall 816. The second trench 804 extends from the back side 404 of the wafer 400 to a second trench terminus 820 (e.g., the second trench terminus 230 of FIG. 2) at the second active surface 516 of the active circuitry 500.

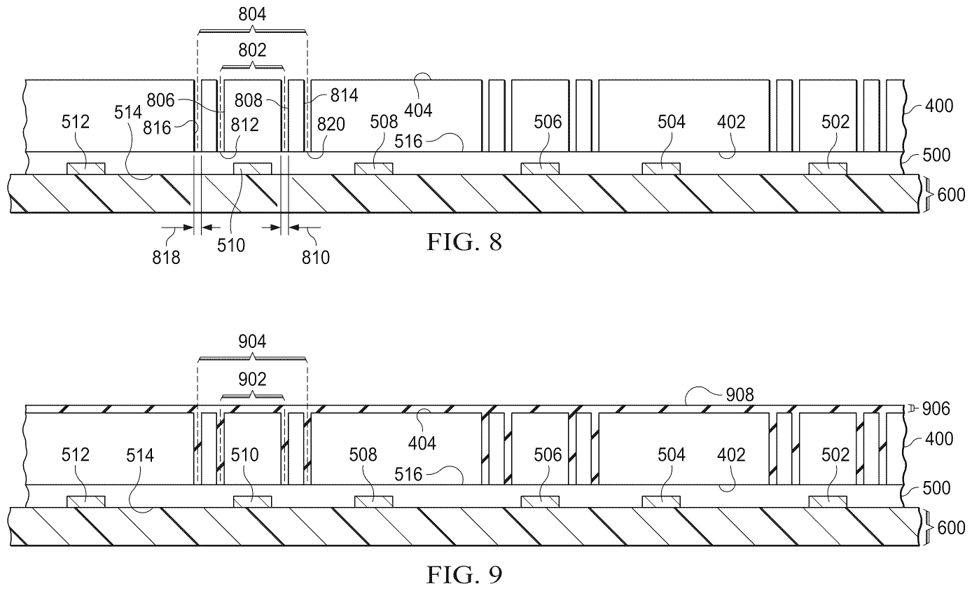

FIG. 9 illustrates an example of a sixth stage of the method for forming the IC device. In the sixth stage, the first trench 802 and the second trench 804 are filled with a dielectric material to form a first filled trench 902 (e.g., the first filled trench 112 of FIG. 1, the first filled trench 222 of FIG. 2) and a second filled trench 904 (e.g., the second filled trench 114 of FIG. 1, the second filled trench 224 of FIG. 2) respectively. The dielectric material is one or more of parylene, polyimide (PI), spin-on-glass material, benzocyclobutene (BCB), liquid crystal polymer, epoxy, polyphenylene ether, polyetherimide, polysulfone, silicon nitride, and silicon dioxide. The first filled trench 902 and the second filled trench 904 form a trench isolation structure that does not extend into the active circuitry 500. The trench isolation structure can be tailored to high voltage applications by changing the sizes and shapes of the first filled trench 902 and the second filled trench 904 to achieve a desired floating voltage based on the component integrated with or connected to the active circuitry 500.

In some examples, the first trench 802 and the second trench 804 are overfilled to form an insulation layer 906 (e.g., the insulation layer 248 of FIG. 2) over the back side 404. Accordingly, the trench isolation structure may include the insulation layer 906. In some examples, the upper surface 908 of the insulation layer 906 is patterned so that the upper surface 908 is at least partially planar.

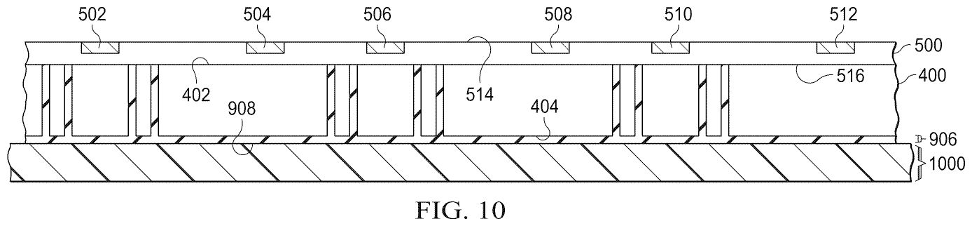

FIG. 10 illustrates an example of a seventh stage of the method for forming the IC device. In the seventh stage, the back grinding tape 600 is removed from a first active surface 514 and a dicing tape 1000 is applied to the upper surface 908 of the insulation layer 906. As one example, the dicing tape 1000 is an ultraviolet (UV) tape. In some examples, the wafer 400 with the dicing tape 1000 is positioned on a carrier, frame, or other suitable surface to support the wafer 400 during a singulation process.

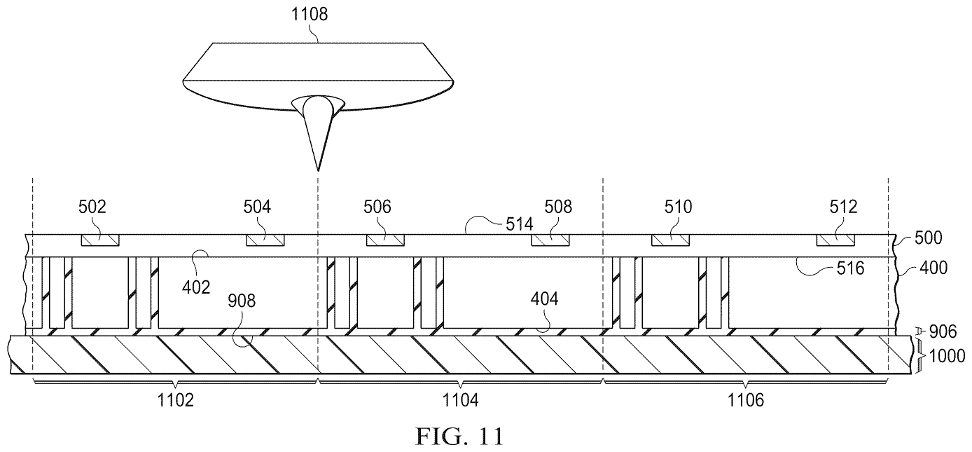

FIG. 11 illustrates an example of an eighth stage of the method of forming the IC device. In the eighth stage, the wafer 400 is singulated into a first semiconductor die 1102, a second semiconductor die 1104, and a third semiconductor die 1106. The wafer 400 is singulated using a severing tool 1108. For example, the severing tool 1108 is a saw that includes a saw blade that scribes, saws or dices through the active circuitry 500 and the wafer 400 in the first direction. Other severing tools (e.g., lasers, grinders, etc.) can be used in other examples.

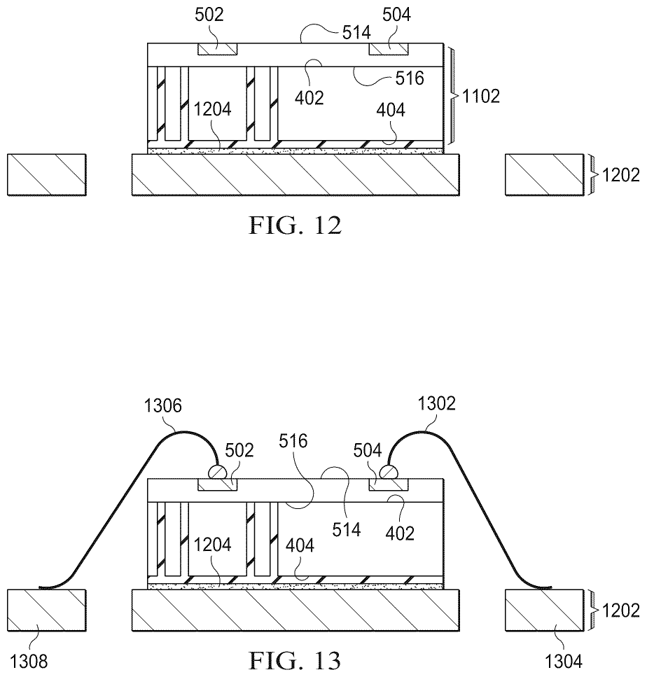

FIG. 12 illustrates an example of a ninth stage of the method of forming the IC device. For clarity, the remaining stages will be shown and described with respect to a single die although the dies may be in strip form or provided on a carrier. In the ninth stage, a die 1102 is affixed to an interconnect. For example, the die 1102 may be attached to a die attach pad 1202 with a bond layer 1204.

FIG. 13 illustrates an example of a tenth stage of the method of the IC device. For example, in the tenth stage, a first bond wire 1302 (e.g., bond wires 314 of FIG. 3) is attached at the first bond pad structure 502 to a first lead 1304 (e.g., the conductive leads 312 of FIG. 3) resulting in an IC device. Additionally, a second bond wire 1306 (e.g., bond wires 314 of FIG. 3) is attached at the second bond pad structure 504 to a second lead 1308 (e.g., the conductive leads 312 of FIG. 3). The first bond wire 1302 and the second bond wire 1306 form an electrical connection between the die 1102 and the leads 1304, 1308.

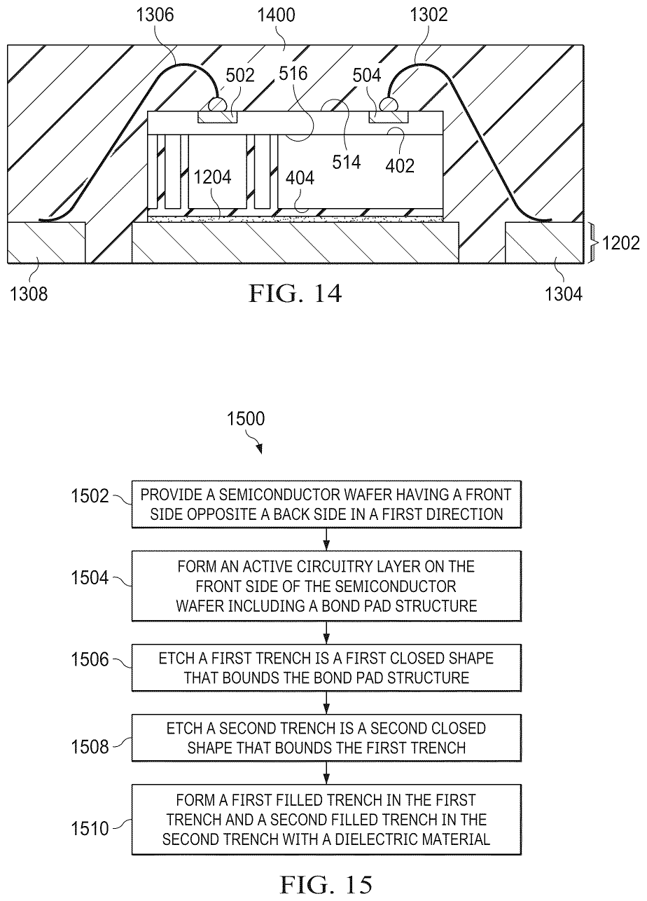

FIG. 14 illustrates an example of an eleventh stage of the method of forming a semiconductor device. In the eleventh stage, the semiconductor device is incapsulated in a mold compound 1400 (e.g., the protective coating 110 of FIG. 1, the mold compound 250 of FIG. 2, the mold compound 310 of FIG. 3). In some examples, the mold compound 1400 is formed of one or more insulating materials, such as organic resins (e.g., epoxy), inorganic fillers, and/or other suitable materials.

FIG. 15 illustrates a flowchart of a method 1500 for fabricating a semiconductor device having an insulation structure. FIG. 15 will also be described with reference to FIGS. 1-14. For simplicity, the method 1500 will be described as a sequence of blocks, but it is understood that the elements of the method 1500 can be organized into different architectures, elements, stages, and/or processes.

At block 1502, the method 1500 includes providing a semiconductor wafer (e.g., (e.g., the wafer 202 of FIG. 2, the wafer 302 of FIG. 3, the wafer 400 of FIG. 4) having a front side (e.g., the front side 204 of FIG. 2) opposite a back side (e.g., the back side 206 of FIG. 2) in a first direction.

At block 1504, the method 1500 includes forming an active circuitry layer (e.g., the active circuitry 208 of FIG. 2, the active circuitry 304 of FIG. 3, the active circuitry 500 of FIG. 5) on the on the front side of the semiconductor wafer. The active circuitry layer includes a bond pad structure (e.g., the first bond pad structure 106 and the second bond pad structure 108 of FIG. 1, and the first bond pad structure 214 and the second bond pad structure 216 of FIG. 2, the bond pad structures 308 of FIG. 3, bond pad structures 502-512 of FIG. 5) on a first active surface opposite a second active surface in the first direction. The second active surface is in contact with the front side of the semiconductor wafer.

At block 1506, the method 1500 includes etching a first trench (e.g., the first trench 802 of FIG. 8). The first trench is a first closed shape that bounds the bond pad structure and extends through the semiconductor wafer from the front side to the back side.

At block 1508, the method 1500 includes etching second trench (e.g., the second trench 804 of FIG. 8) is a second closed shape that bounds the first trench and extends through the semiconductor wafer from the front side to the back side; and

At block 1510, the method 1500 includes forming a first filled trench (e.g., the first filled trench 112 of FIG. 1, the first filled trench 222 of FIG. 2, the first filled trench 902 of FIG. 9) in the first trench and a second filled trench (e.g., the second filled trench 114 of FIG. 1, the second filled trench 224 of FIG. 2, the second filled trench 904 of FIG. 9) in the second trench with a dielectric material. The first filled trench and the second filled trench form a trench isolation structure that does not impact the active circuitry. The trench isolation structure can be tailored to high voltage applications by changing the sizes and shapes of the first filled trench and the second filled trench to achieve a desired floating voltage. Additional filled trenches may also be added to the isolation trench structure to increase the floating voltage. Furthermore, because the plurality of filled trenches are formed through the back side of the wafer, the trench structure described herein negates the need for an insulation layer between the wafer and the active circuitry.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

A “value” as used herein may include, but is not limited to, a numerical or other kind of value or level such as a percentage, a non-numerical value, a discrete state, a discrete value, a continuous value, among others. The term “value of X” or “level of X” as used throughout this detailed description and in the claims refers to any numerical or other kind of value for distinguishing between two or more states of X. For example, in some cases, the value of X may be given as a percentage between 0% and 100%. In other cases, the value of X could be a value in the range between 1 and 10. In still other cases, the value of X may not be a numerical value, but could be associated with a given discrete state, such as “not X”, “slightly x”, “x”, “very x” and “extremely x”.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A semiconductor device comprising:
a semiconductor wafer having a front side opposite a back side in a first direction;
active circuitry layer formed on the front side of the semiconductor wafer, the active circuitry layer including a bond pad structure on a first active surface opposite a second active surface in the first direction, wherein the second active surface affixed to the front side of the semiconductor wafer;
a first filled trench is a first closed shape that bounds the bond pad structure and extends through the semiconductor wafer from the front side to the back side; and
a second filled trench arranged is a second closed shape that bounds the first filled trench and extends through the semiconductor wafer from the front side to the back side.

2. The semiconductor device of claim 1, wherein the first filled trench and the second filled trench are formed of a dielectric material that extends from an insulation surface to a trench terminus at the second active surface of the active circuitry layer.

3. The semiconductor device of claim 2, wherein an insulation layer extends from the back side of the semiconductor wafer to the insulation surface.

4. The semiconductor device of claim 2, wherein the dielectric material is one or more of parylene, polyimide (PI), spin-on-glass material, Benzocyclobutene (BCB), liquid crystal polymer, epoxy, polyphenylene ether, polyetherimide, polysulfone, silicon nitride, and silicon dioxide.

5. The semiconductor device of claim 1, wherein the bond pad structure is a first bond pad structure and the active circuitry layer further comprises a second bond pad structure, wherein the first filled trench and the second filled trench separate the first bond pad structure and the second bond pad structure forming a high voltage region between the first filled trench and the first bond pad structure and a low voltage region about the second bond pad structure.

6. The semiconductor device of claim 5, further comprising:
a first bond wire coupled between the first bond pad structure and a first lead,
a second bond wire coupled between the second bond pad structure and a second lead; and
mold compound encapsulating the first bond wire, the second bond wire, the first lead, the second lead, and the first active surface.

7. The semiconductor device of claim 1, wherein the first filled trench has a first inner sidewall opposite a first outer sidewall in a second direction approximately orthogonal to the first direction, the first inner sidewall formed between the bond pad structure and the first outer sidewall.

8. The semiconductor device of claim 7, wherein the first filled trench has a first trench thickness defined as a distance between the first inner sidewall and the first outer sidewall, and wherein the semiconductor wafer has a semiconductor thickness that is at least approximately ten times the first trench thickness.

9. The semiconductor device of claim 1, wherein the first filled trench has a first trench thickness and the second filled trench has a second trench thickness, and wherein a first capacitance value of the first filled trench is based on the first trench thickness and a second capacitance value of the second filled trench is based on the second trench thickness.

10. The semiconductor device of claim 9, wherein a floating voltage of the semiconductor device is based on an application of the semiconductor device, and the floating voltage is calculated based on the first capacitance value and the second capacitance value.

11. The semiconductor device of claim 1, wherein the first closed shape and the second closed shape are quadrilaterals having four edges and four rounded corners.

12. A method for forming semiconductor device, the method comprising:
providing a semiconductor wafer having a front side opposite a back side in a first direction;
forming an active circuitry layer on the front side of the semiconductor wafer, the active circuitry layer including a bond pad structure on a first active surface opposite a second active surface in the first direction, wherein the second active surface is in contact with the front side of the semiconductor wafer;
etching a first trench is a first closed shape that bounds the bond pad structure and extends through the semiconductor wafer from the front side to the back side;
etching second trench is a second closed shape that bounds the first trench and extends through the semiconductor wafer from the front side to the back side; and
forming a first filled trench in the first trench and a second filled trench in the second trench with a dielectric material.

13. The method of claim 12, further comprising:
forming an insulation layer extending from the back side of the semiconductor wafer to an insulation surface, wherein the first filled trench and the second filled trench are formed of the dielectric material that extends from the insulation surface to a trench terminus at the second active surface of the active circuitry layer.

14. The method of claim 12, wherein the bond pad structure is a first bond pad structure and the active circuitry layer further comprises a second bond pad structure, wherein the first filled trench and the second filled trench separate the first bond pad structure and the second bond pad structure forming a high voltage region between the first filled trench and the first bond pad structure and a low voltage region at the second bond pad structure.

15. The method of claim 12, wherein the first filled trench has a first inner sidewall opposite a first outer sidewall in a second direction approximately orthogonal to the first direction, the first inner sidewall formed between the bond pad structure and the first outer sidewall, wherein a first trench thickness is defined between the first inner sidewall and the first outer sidewall.

16. The method of claim 12, wherein the first filled trench has a first trench thickness and the second filled trench has a second trench thickness, and wherein a first capacitance value of the first filled trench is based on the first trench thickness and a second capacitance value of the second filled trench is based on the second trench thickness.

17. The method of claim 16, wherein a floating voltage of the semiconductor device is determined based on an application of the semiconductor device, and the floating voltage is determined based on the first capacitance and the second capacitance.

18. An integrated circuit (IC) device comprising:
a semiconductor wafer having a front side opposite a back side in a first direction;
active circuitry layer formed on the front side of the semiconductor wafer, the active circuitry layer including a first bond pad structure and a second bond pad structure on a first active surface opposite a second active surface in the first direction, wherein the second active surface is in contact with the front side of the semiconductor wafer;
a first filled trench is a first closed shape that bounds the first bond pad structure and extends through the semiconductor wafer from the front side to the back side; and
a second filled trench is a second closed shape that bounds the first filled trench and extends through the semiconductor wafer from the front side to the back side, wherein the first filled trench and the second filled trench separate the first bond pad structure and the second bond pad structure forming a high voltage region between the first filled trench and the first bond pad structure and a low voltage region at the second bond pad structure.

19. The IC device of claim 18, wherein a floating voltage of the IC device is determined based on an application of the IC device, and the floating voltage is determined based on a first capacitance of the first filled trench and a second capacitance of the second filled trench.

20. The IC device of claim 19, wherein the application of the IC device is a maximum repetitive peak isolation application.
